(19) United States
(12) Patent Application Publication
(10) Pub. No.: US 2023/0344405 A1
(43) Pub. Date: Oct. 26, 2023

(54) ACOUSTIC WAVE DEVICE

(71) Applicant: Murata Manufacturing Co., Ltd., Nagaokakyo-shi (JP)

(72) Inventors: Katsuya DAIMON, Nagaokakyo-shi (JP); Kentaro NAKAMURA, Nagaokakyo-shi (JP)

(21) Appl. No.: 18/217,678

(22) Filed: Jul. 3, 2023

Related U.S. Application Data
(63) Continuation of application No. PCT/JP2022/003619, filed on Jan. 31, 2022.

(30) Foreign Application Priority Data
Feb. 4, 2021 (JP) 2021-016821

(51) Int. Cl. H03H 9/02; H03H 9/145; H03H 9/25

(52) U.S. Cl. CPC H03H 9/02574; H03H 9/02559; H03H 9/02637; H03H 9/02866; H03H 9/145; H03H 9/25

(57) ABSTRACT

An acoustic wave device includes a crystal substrate, an aluminum oxide layer on the crystal substrate, a lithium tantalate layer on the aluminum oxide layer, and an interdigital transducer electrode on the lithium tantalate layer and including multiple first and second electrode fingers.

### CROSS REFERENCE TO RELATED APPLICATIONS

This application claims the benefit of priority to Japanese Patent Application No. 2021-016821 filed on Feb. 4, 2021 and is a Continuation Application of PCT Application No. PCT/JP2022/003619 filed on Jan. 31, 2022. The entire contents of each application are hereby incorporated herein by reference.

### BACKGROUND OF THE INVENTION

### 1. Field of the Invention

The present invention relates to an acoustic wave device.

### 2. Description of the Related Art

Acoustic wave devices have been widely used for various purposes, such as filters for mobile phones. Japanese Unexamined Patent Application Publication No. 2019-145895 discloses an example of an acoustic wave device. This acoustic wave device includes a support substrate, a high velocity film, a low velocity film, and a piezoelectric layer laminated in this order. An interdigital transducer (IDT) electrode is disposed on the piezoelectric layer. The high velocity film is formed from SiNₓ. Here, x<0.67, and thus, the higher order mode is reduced.

However, the acoustic wave device described in Japanese Unexamined Patent Application Publication No. 2019-145895 is not suitable for reducing a higher order mode in a wide band.

### SUMMARY OF THE INVENTION

Preferred embodiments of the present invention provide acoustic wave devices that are each able to reduce or prevent a higher order mode in a wide band of frequencies higher than or equal to about 1.5 times of the resonance frequency.

An acoustic wave device according to a preferred embodiment of the present invention includes a crystal substrate, an aluminum oxide layer on the crystal substrate, a piezoelectric layer on the aluminum oxide layer, and an interdigital transducer electrode on the piezoelectric layer and including multiple electrode fingers.

Acoustic wave devices according to preferred embodiments of the present invention are able to reduce or prevent a higher order mode in a wide band of frequencies higher than or equal to about 1.5 times of the resonance frequency.

The above and other elements, features, steps, characteristics and advantages of the present invention will become more apparent from the following detailed description of the preferred embodiments with reference to the attached drawings.

### BRIEF DESCRIPTION OF THE DRAWINGS

FIG. 1 is a cross-sectional view, viewed from the front, of a portion of an acoustic wave device according to a first preferred embodiment of the present invention.

FIG. 2 is a plan view of the acoustic wave device according to the first preferred embodiment of the present invention.

FIG. 3 is a schematic diagram of the coordinate systems of Euler angles.

FIG. 4 is a diagram showing phase characteristics of acoustic wave devices according to the first preferred embodiment of the present invention and according to a comparative example.

FIG. 5 is a cross-sectional view, viewed from the front, of a portion of an acoustic wave device according to a modified example for the first preferred embodiment of the present invention.

FIG. 6 is a graph showing the relationship between θ in the Euler angles of a crystal substrate, a thickness t of an aluminum oxide layer, and a Z ratio.

FIG. 7 is a graph showing the relationship between θ in the Euler angles of the crystal substrate, the thickness t of the aluminum oxide layer, and a phase of the higher order mode.

FIG. 8 is a stereographic projection showing symmetry of acoustic vibrations in quartz crystal.

FIG. 9 is a graph showing phase characteristics of acoustic wave devices according to a second preferred embodiment and a third preferred embodiment of the present invention.

### DETAILED DESCRIPTION OF THE PREFERRED EMBODIMENTS

With reference to the drawings, preferred embodiments of the present invention are described below with reference to the drawings to clarify the present invention.

Each preferred embodiment described herein is merely an example, and components between different preferred embodiments may be partially replaced with each other or combined with each other.

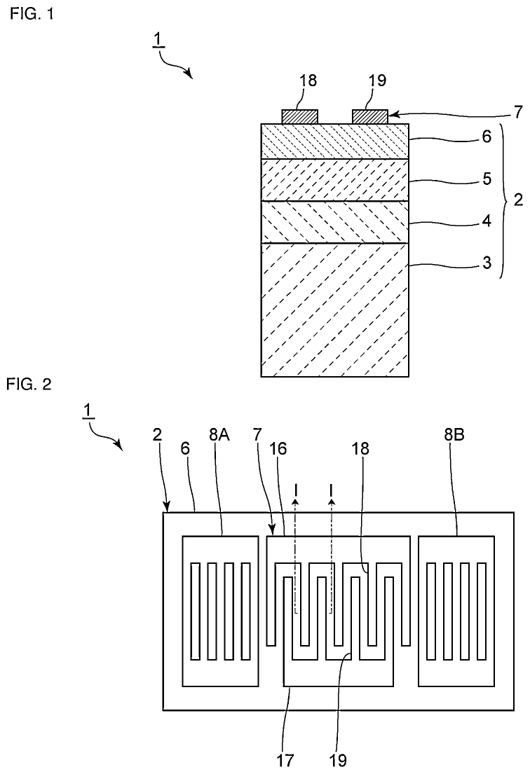

FIG. 1 is a cross-sectional view, viewed from the front, of a portion of an acoustic wave device according to a first preferred embodiment of the present invention. FIG. 2 is a plan view of the acoustic wave device according to the first preferred embodiment. FIG. 1 is a cross-sectional view taken along line I-I in FIG. 2.

As illustrated in FIG. 1, an acoustic wave device 1 includes a piezoelectric substrate 2. The piezoelectric substrate 2 includes, for example, a crystal substrate 3, an aluminum oxide layer 4, a low velocity film 5, and a lithium tantalate layer 6. More specifically, the aluminum oxide layer 4 is disposed on the crystal substrate 3. The low velocity film 5 is disposed on the aluminum oxide layer 4. The lithium tantalate layer 6 is disposed on the low velocity film 5. The piezoelectric layer included in the piezoelectric substrate is not limited to a lithium tantalate layer, and may be, for example, a lithium niobate layer.

An IDT electrode 7 is disposed on the lithium tantalate layer 6. When an alternating current voltage is applied to the IDT electrode 7, acoustic waves are excited. As illustrated in FIG. 2, a pair of reflectors 8A and 8B are disposed on the lithium tantalate layer 6 on both sides in a propagation direction in which the acoustic waves propagate. As described above, the acoustic wave device 1 according to the present preferred embodiment is, for example, a surface acoustic wave resonator. However, the acoustic wave device according to preferred embodiments of the present invention is not limited to an acoustic wave resonator, and may be, for example, a multiplexer or a filter device including multiple acoustic wave resonators.

The low velocity film 5 illustrated in FIG. 1 is a film with a relatively low velocity. More specifically, a bulk wave that propagates through the low velocity film 5 has a lower velocity than a bulk wave that propagates through the lithium tantalate layer 6. In the present preferred embodiment, the low velocity film 5 is, for example, a silicon oxide film. The material of the low velocity film 5 is not limited to the above example. The low velocity film 5 may be made of, for example, glass, a silicon oxynitride, a lithium oxide, a tantalum pentoxide, or a compound obtained by adding fluorine, carbon, or boron to a silicon oxide as a main component.

As described above, the piezoelectric substrate 2 includes the crystal substrate 3 and the lithium tantalate layer 6. Thus, the piezoelectric substrate 2 has a small difference in a coefficient of linear expansion, and thus can improve frequency temperature characteristics. The low velocity film 5 made of a silicon oxide film can reduce an absolute value of the temperature coefficient of frequency (TCF) in the piezoelectric substrate 2, and thus can further improve the frequency temperature characteristics. Instead, the low velocity film 5 may be eliminated.

The lithium tantalate layer 6 preferably has a cut-angle of, for example, about 20°-rotated Y-cut X-propagation to about 60°-rotated Y-cut X-propagation. Thus, an acoustic wave element having a preferable electromechanical coupling coefficient and a preferable Q value can be obtained. Similarly, also when the piezoelectric layer is a lithium niobate layer, the lithium niobate layer preferably has a cut-angle of, for example, about 20°-rotated Y-cut X-propagation to about 60°-rotated Y-cut X-propagation.

In the present preferred embodiment, a bulk wave that propagates through the crystal substrate 3 has a lower velocity than an acoustic wave that propagates through the lithium tantalate layer 6. More specifically, a slow transversal wave that propagates through the crystal substrate 3 has a lower velocity than a surface acoustic wave that propagates through the lithium tantalate layer 6. However, the relationship in velocity between the crystal substrate 3 and the lithium tantalate layer 6 is not limited to the above.

As illustrated in FIG. 2, the IDT electrode 7 includes a first busbar 16, a second busbar 17, multiple first electrode fingers 18, and multiple second electrode fingers 19. The first busbar 16 and the second busbar 17 face each other. One end of each of the multiple first electrode fingers 18 is connected to the first busbar 16. One end of each of the multiple second electrode fingers 19 is connected to the second busbar 17. The multiple first electrode fingers 18 and the multiple second electrode fingers 19 interdigitate with one another. The IDT electrode 7, the reflector 8A, and the reflector 8B may each be a multilayer metal film or a single-layer metal film.

A wavelength defined by an electrode finger pitch of the IDT electrode 7 is defined as λ. The lithium tantalate layer 6 has a thickness of, for example, smaller than or equal to about 1λ. This structure can thus preferably improve excitation efficiency. The electrode finger pitch is a center distance between adjacent electrode fingers.

In the present preferred embodiment, the piezoelectric substrate 2 includes the crystal substrate 3, the aluminum oxide layer 4, and the lithium tantalate layer 6. The piezoelectric substrate 2 having the above structure can set, for example, the mode of frequencies around 2.2 times of the resonant frequency to a leaky mode. This structure can thus reduce a higher order mode in a wide band of frequencies higher than or equal to about 1.5 times of the resonance frequency. The details of the advantageous effects are described below by comparing the present preferred embodiment and a comparative example.

The comparative example differs from the first preferred embodiment in that a piezoelectric substrate is a multilayer body including a silicon substrate, a silicon nitride film, a silicon oxide film, and a lithium tantalate layer. The acoustic wave device 1 according to the first preferred embodiment and an acoustic wave device according to the comparative example are compared in terms of phase characteristics. The acoustic wave device 1 according to the first preferred embodiment has design parameters below.
crystal substrate 3: Euler angles (φ, θ, ψ) of (about 0°, about 185°, about 90°)
aluminum oxide layer 4: a thickness of about 1.8 μm
low velocity film 5: a material of SiO₂ and a thickness of about 300 nm
lithium tantalate layer 6: a material of LiTaO₃ and a thickness of about 400 nm
IDT electrode 7: a layer structure including a Ti layer, an AlCu layer, and a Ti layer sequentially laminated on the lithium tantalate layer 6, thicknesses of about 12 nm, about 100 nm, and about 4 nm from the side closer to the lithium tantalate layer 6, a wavelength λ of about 2 μm, and a duty of about 0.5

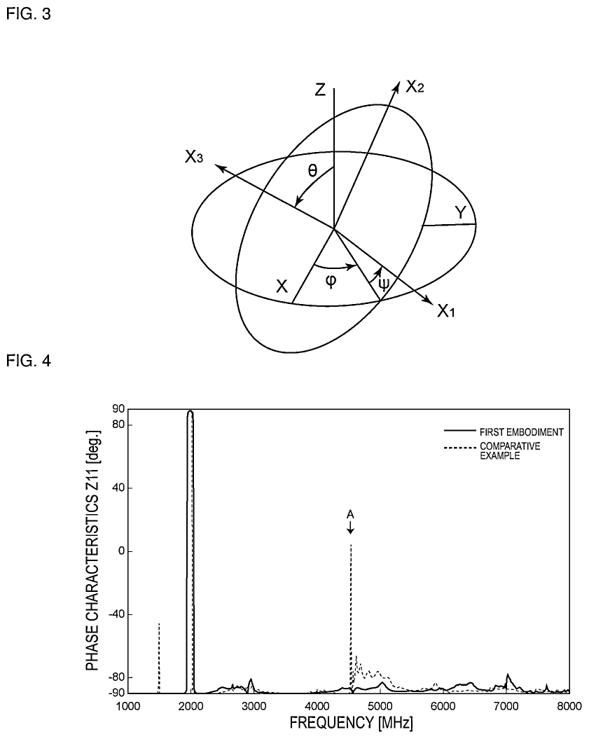

Herein, unless otherwise specified, the orientations of the crystal substrate 3 are indicated with the Euler angles. The coordinate systems of the Euler angles are coordinate systems illustrated in FIG. 3, and differ from polar coordinate systems. In FIG. 3, initial coordinate axes are indicated with an X axis, a Y axis, and a Z axis, and vectors after rotations at φ°, θ°, and ψ° are indicated with X₁, X₂, and X₃.

FIG. 4 is a diagram of phase characteristics of acoustic wave devices according to the first preferred embodiment of the present invention and according to a comparative example.

As indicated with arrow A in FIG. 4, a comparative example fails to reduce a higher order mode of frequencies around 2.2 times of the resonant frequency. In contrast, the first preferred embodiment can successfully reduce or prevent a higher order mode in a wide band including a mode of frequencies around 2.2 times of the resonant frequency. The present preferred embodiment can also successfully reduce or prevent a higher order mode in a band of, for example, frequencies lower than or equal to about 1.5 times of the resonance frequency.

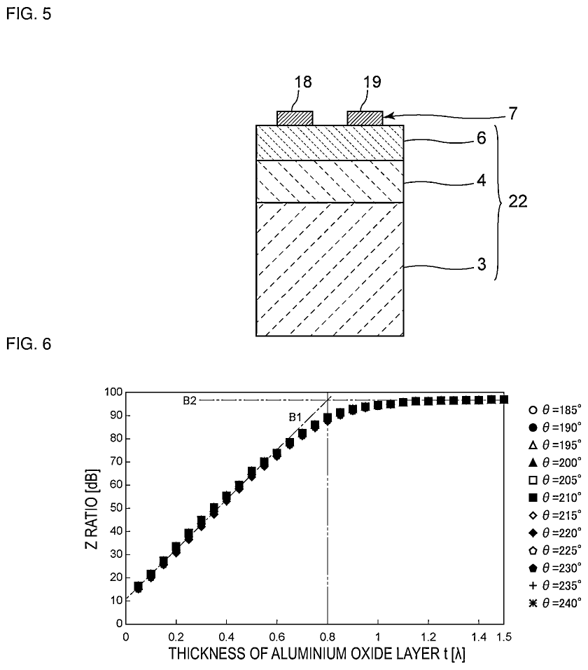

In the piezoelectric substrate 2, the lithium tantalate layer 6 is indirectly disposed on the aluminum oxide layer 4 with the low velocity film 5 interposed in between. Instead, the piezoelectric substrate 2 may eliminate the low velocity film 5. For example, in a modified example for the first preferred embodiment illustrated in FIG. 5, a piezoelectric substrate 22 is a multilayer body including the crystal substrate 3, the aluminum oxide layer 4, and the lithium tantalate layer 6. In the piezoelectric substrate 22, the lithium tantalate layer 6 is directly disposed on the aluminum oxide layer 4. As in the case of the first preferred embodiment, this structure can also reduce or prevent a higher order mode in a wide band.

In the acoustic wave device 1 according to the first preferred embodiment, the Z ratio and the phase of a higher order mode are measured every time the thickness of the aluminum oxide layer 4 is changed. The Z ratio is an impedance ratio. More specifically, the Z ratio is calculated by dividing the impedance of an anti-resonant frequency with the impedance of the resonant frequency. The phase of the measured higher order mode is a phase component of the impedance in a maximum mode in a spurious mode caused within a range of frequencies of about 1.15 times to about 3 times of the resonant frequency including frequencies of about 2.2 times of the resonant frequency. The thickness of the aluminum oxide layer 4 is changed in about 0.05λ intervals within the range greater than or equal to about 0.05λ to smaller than or equal to about 1.5λ. Thus, the relationship between the thickness of the aluminum oxide layer 4, the Z ratio, and the phase of the higher order mode is obtained. In the following description, the thickness of the aluminum oxide layer 4 is denoted with t.

In addition, θ in the Euler angles (φ, θ, ψ) of the crystal substrate 3 is changed, and the above relationship for θ with each angle is obtained. In the Euler angles of the crystal substrate 3, φ is set at about 0°, and ψ is set at about 90°. The angle θ is changed in about 5° intervals within the range greater than or equal to about 185° and smaller than or equal to about 240°.

FIG. 6 is a graph showing the relationship between θ in the Euler angles of a crystal substrate, the thickness t of the aluminum oxide layer, and the Z ratio. A dot-and-dash line B1 and a dot-and-dash line B2 in FIG. 6 indicate inclination of a change of the Z ratio with respect to a change of the thickness t of the aluminum oxide layer 4.

As illustrated in FIG. 6, regardless of when 0 in the Euler angles of the crystal substrate 3 has any degree, the Z ratio increases further as the thickness t of the aluminum oxide layer 4 increases further. As indicated with the dot-and-dash line B1 and the dot-and-dash line B2, the change of the Z ratio is reduced when t≥about 0.8λ rather than when t<about 0.8λ. Thus, the thickness t of the aluminum oxide layer 4 is preferably t≥about 0.8λ. This structure can reduce or prevent the variation of the Z ratio, and the Z ratio can thus be increased. Thus, the electric characteristics of the acoustic wave device 1 can be stably improved.

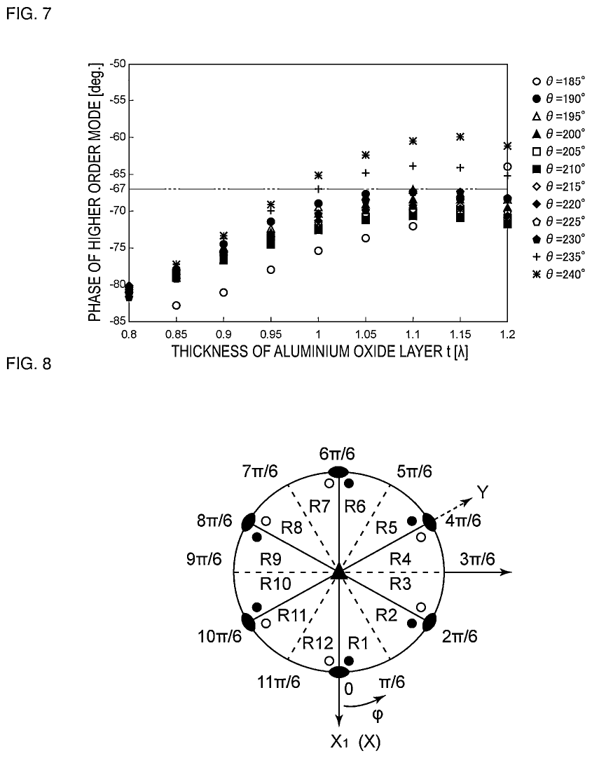

FIG. 7 is a graph showing the relationship between θ in the Euler angles of a crystal substrate, the thickness t of the aluminum oxide layer, and a phase of the higher order mode. The phase illustrated in FIG. 7 is a phase component of the impedance of a maximum mode in a spurious mode caused within a range of frequencies of about 1.15 times to about 3 times of the resonant frequency including frequencies of about 2.2 times of the resonant frequency.

The higher order mode is preferably reduced to be lower than about −67 deg., or more preferably, lower than about −70 deg. As illustrated in FIG. 7, in the range where θ in the Euler angles of the crystal substrate 3 is within the range of about 185°≤θ<about 240°, as long as the thickness t of the aluminum oxide layer 4 satisfies t≤about 0.9λ, the phase of the higher order mode can be reduced to be lower than about −67 deg., or lower than about −70 deg. The detailed range of the thickness t of the aluminum oxide layer 4 where the phase of the higher order mode can be reduced to be smaller than −67 deg. is described as below. When about 185°≤θ<about 190°, the thickness may be t≤about 1.15λ. When about 190°≤θ<about 195°, the thickness may be t≤about 1λ. When about 195°≤θ<about 200°, the thickness may be t about 1λ. When about 200°≤θ<about 205°, the thickness may be t about 1.05λ. When about 205°≤θ<about 210°, the thickness may be t about 1.1λ. When about 210°≤θ<about 215°, the thickness may be t about 1.05λ. When about 215°≤θ<about 220°, the thickness may be t about 1.05λ. When about 220°≤θ<about 225°, the thickness may be t about 1.05λ. When about 225°≤θ<about 230°, the thickness may be t about 1λ. When about 230°≤θ<about 235°, the thickness may be t about 0.95λ. When about 235°≤θ≤about 240°, the thickness may be t about 0.9λ.

It is known that when φ in the Euler angles of the crystal substrate 3 is within the range of about 0°±2.5°, and when ψ is within the range of about 90°±2.5°, the effects on the Z ratio and the higher order mode are small. From the above, preferably, the Euler angles (φ, θ, ψ) of the crystal substrate 3 are (for example, within the range of about 0°±2.5°, about θ, within the range of about 90°±about 2.5°), and the relationship between θ in the Euler angles of the crystal substrate 3 and the thickness t of the aluminum oxide layer 4 is any of the combinations in Table 1. Thus, the Z ratio can be stably increased, and the higher order mode can be effectively reduced.

TABLE 1

| θ [°] of crystal substrate | thickness t [λ] of aluminum oxide layer |
|---|---|
| 185 ≤ θ < 190 | 0.8 ≤ t ≤ 1.15 |
| 190 ≤ θ < 195 | 0.8 ≤ t ≤ 1 |
| 195 ≤ θ < 200 | 0.8 ≤ t ≤ 1 |
| 200 ≤ θ < 205 | 0.8 ≤ t ≤ 1.05 |
| 205 ≤ θ < 210 | 0.8 ≤ t ≤ 1.1 |
| 210 ≤ 0 ≤ 215 | 0.8 ≤ t ≤ 1.05 |
| 215 ≤ θ < 220 | 0.8 ≤ t ≤ 1.05 |
| 220 ≤ θ < 225 | 0.8 ≤ t ≤ 1.05 |
| 225 ≤ θ < 230 | 0.8 ≤ t ≤ 1 |
| 230 ≤ θ < 235 | 0.8 ≤ t ≤ 0.95 |
| 235 ≤ 0 ≤ 240 | 0.8 ≤ t ≤ 0.9 |

As described above, in the first preferred embodiment, a bulk wave that propagates through the crystal substrate 3 has a lower velocity than an acoustic wave that propagates through the lithium tantalate layer 6. Thus, the crystal substrate 3 can leak a higher order mode, and thus can effectively reduce the higher order mode. For example, the Euler angles (about 0°, about 185°, about 90°) of the crystal substrate 3 of the acoustic wave device 1 exhibiting the phase characteristic in FIG. 4 have the above velocity relationship. For example, despite when the Euler angles of the crystal substrate 3 are within the range of (φ, θ, ψ) listed in Table 2 to Table 14, a bulk wave that propagates through the crystal substrate 3 has a lower velocity than an acoustic wave that propagates through the lithium tantalate layer 6.

In Table 2 to Table 14, each of the Euler angles (φ, θ, ψ) has a degree within the range of about ±2.5°. More specifically, in Table 2, φ is within the range of about −2.5°≤φ<about 2.5°, and in Table 3, φ is within the range of about 2.5°≤φ<about 7.5°. Thus, in Table 2 to Table 14, φ increments by about 5°. In Table 14, φ is within the range of about 57.5°≤φ≤about 62.5°. Each table shows the range of θ when φ is within a fixed range, and the range of ψ is changed in about 5° intervals. More specifically, when, for example, ψ is described as about 0° in each table, the range of θ where about −2.5°≤ψ<about 2.5° is described, and when ψ is described as about 5°, the range of θ where about 2.5°≤ψ<about 7.5° is described. When ψ is described as about 175°, the range of θ where about 172.5°≤ψ≤about 177.5° is described. The range of θ in each table also shows the range of higher than or equal to about −2.5° of the described lower limit and smaller than or equal to about +2.5° of the described upper limit.

TABLE 2
(ϕ[°], θ[°], ψ[°])

| | | | | |
|---|---|---|---|---|
| (0, 0-175, 0) | (0, 0-175, 5) | (0, 0-175, 10) | (0, 0-175, 15) | (0, 0-15, 20) |
| (0, 65-175, 20) | (0, 85-175, 25) | (0, 90-170, 30) | (0, 90-175, 35) | (0, 0-5, 40) |
| (0, 85-175, 40) | (0, 0-10, 45) | (0, 80-175, 45) | (0, 0-15, 50) | (0, 75-175, 50) |
| (0, 0-20, 55) | (0, 65-175, 55) | (0, 0-25, 60) | (0, 55-175, 60) | (0, 0-35, 65) |
| (0, 45-70, 65) | (0, 110-140, 65) | (0, 150-175, 65) | (0, 0-65, 70) | (0, 115-135, 70) |
| (0, 165-175, 70) | (0, 0-60, 75) | (0, 120-135, 75) | (0, 170-175, 75) | (0, 0-60, 80) |
| (0, 120-130, 80) | (0, 5-60, 85) | (0, 120-130, 85) | (0, 5-60, 90) | (0, 120-130, 90) |
| (0, 5-60, 95) | (0, 120-130, 95) | (0, 0-60, 100) | (0, 120-130, 100) | (0, 0-60, 105) |
| (0, 120-135, 105) | (0, 170-175, 105) | (0, 0-65, 110) | (0, 115-135, 110) | (0, 165-175, 110) |
| (0, 0-35, 115) | (0, 45-70, 115) | (0, 110-140, 115) | (0, 150-175, 115) | (0, 0-25, 120) |
| (0, 55-175, 120) | (0, 0-20, 125) | (0, 65-175, 125) | (0, 0-15, 130) | (0, 75-175, 130) |
| (0, 0-10, 135) | (0, 80-175, 135) | (0, 0-5, 140) | (0, 85-175, 140) | (0, 90-175, 145) |
| (0, 90-170, 150) | (0, 85-175, 155) | (0, 0-15, 160) | (0, 65-175, 160) | (0, 0-175, 165) |
| (0, 0-175, 170) | (0, 0-175, 175) | | | |

TABLE 3
(ϕ[°], θ[°], ψ[°])

| | | | | |
|---|---|---|---|---|
| (5, 0-175, 0) | (5, 0-175, 5) | (5, 0-175, 10) | (5, 0-25, 15) | (5, 55-175, 15) |
| (5, 85-175, 20) | (5, 95-175, 25) | (5, 100-175, 30) | (5, 0-5, 35) | (5, 100-170, 35) |
| (5, 0-15, 40) | (5, 90-175, 40) | (5, 0-20, 45) | (5, 85-175, 45) | (5, 0-25, 50) |
| (5, 75-175, 50) | (5, 0-30, 55) | (5, 65-175, 55) | (5, 0-35, 60) | (5, 50-175, 60) |
| (5, 0-70, 65) | (5, 110-175, 65) | (5, 0-65, 70) | (5, 115-140, 70) | (5, 155-175, 70) |
| (5, 0-60, 75) | (5, 120-135, 75) | (5, 165-175, 75) | (5, 5-60, 80) | (5, 120-135, 80) |
| (5, 170-175, 80) | (5, 5-60, 85) | (5, 120-130, 85) | (5, 5-60, 90) | (5, 120-130, 90) |
| (5, 0-60, 95) | (5, 120-130, 95) | (5, 0-60, 100) | (5, 120-130, 100) | (5, 0-60, 105) |
| (5, 120-130, 105) | (5, 0-65, 110) | (5, 115-135, 110) | (5, 170-175, 110) | (5, 0-25, 115) |
| (5, 50-70, 115) | (5, 110-135, 115) | (5, 160-175, 115) | (5, 0-20, 120) | (5, 60-175, 120) |
| (5, 0-15, 125) | (5, 65-175, 125) | (5, 0-10, 130) | (5, 70-175, 130) | (5, 0-5, 135) |
| (5, 75-175, 135) | (5, 80-175, 140) | (5, 85-175, 145) | (5, 85-175, 150) | (5, 0-10, 155) |
| (5, 70-170, 155) | (5, 0-175, 160) | (5, 0-175, 165) | (5, 0-175, 170) | (5, 0-175, 175) |

TABLE 4
(ϕ[°], θ[°], ψ[°])

| | | | | |
|---|---|---|---|---|
| (10, 0-175, 0) | (10, 0-175, 5) | (10, 0-175, 10) | (10, 85-175, 15) | (10, 100-175, 20) |
| (10, 105-175, 25) | (10, 0-5, 30) | (10, 110-175, 30) | (10, 0-15, 35) | (10, 110-175, 35) |
| (10, 0-20, 40) | (10, 100-170, 40) | (10, 0-25, 45) | (10, 85-175, 45) | (10, 0-30, 50) |
| (10, 75-175, 50) | (10, 0-35, 55) | (10, 60-175, 55) | (10, 0-175, 60) | (10, 0-70, 65) |
| (10, 110-175, 65) | (10, 0-65, 70) | (10, 115-175, 70) | (10, 5-60, 75) | (10, 120-140, 75) |
| (10, 155-175, 75) | (10, 5-60, 80) | (10, 120-135, 80) | (10, 165-175, 80) | (10, 5-60, 85) |
| (10, 120-135, 85) | (10, 170-175, 85) | (10, 0-60, 90) | (10, 120-130, 90) | (10, 0-60, 95) |
| (10, 120-130, 95) | (10, 0-60, 100) | (10, 120-130, 100) | (10, 0-60, 105) | (10, 120-130, 105) |
| (10, 0-25, 110) | (10, 45-65, 110) | (10, 115-130, 110) | (10, 175-175, 110) | (10, 0-20, 115) |
| (10, 55-70, 115) | (10, 110-130, 115) | (10, 170-175, 115) | (10, 0-15, 120) | (10, 60-135, 120) |
| (10, 160-175, 120) | (10, 0-10, 125) | (10, 65-175, 125) | (10, 0-5, 130) | (10, 70-175, 130) |
| (10, 75-175, 135) | (10, 75-175, 140) | (10, 80-175, 145) | (10, 0-10, 150) | (10, 70-175, 150) |
| (10, 0-175, 155) | (10, 0-165, 160) | (10, 0-175, 165) | (10, 0-175, 170) | (10, 0-175, 175) |

TABLE 5
(ϕ[°], θ[°], ψ[°])

| | | | | |
|---|---|---|---|---|
| (15, 0-175, 0) | (15, 0-175, 5) | (15, 90-175, 10) | (15, 105-175, 15) | (15, 110-175, 20) |
| (15, 0-10, 25) | (15, 115-175, 25) | (15, 0-15, 30) | (15, 115-175, 30) | (15, 0-25, 35) |
| (15, 115-175, 35) | (15, 0-25, 40) | (15, 105-175, 40) | (15, 0-30, 45) | (15, 90-170, 45) |
| (15, 0-35, 50) | (15, 75-175, 50) | (15, 0-175, 55) | (15, 0-175, 60) | (15, 0-70, 65) |
| (15, 110-175, 65) | (15, 5-65, 70) | (15, 115-175, 70) | (15, 5-60, 75) | (15, 120-175, 75) |
| (15, 5-60, 80) | (15, 120-140, 80) | (15, 160-175, 80) | (15, 0-60, 85) | (15, 120-135, 85) |
| (15, 165-175, 85) | (15, 0-60, 90) | (15, 120-135, 90) | (15, 170-175, 90) | (15, 0-60, 95) |
| (15, 120-130, 95) | (15, 0-60, 100) | (15, 120-130, 100) | (15, 0-25, 105) | (15, 45-60, 105) |
| (15, 120-130, 105) | (15, 0-20, 110) | (15, 50-65, 110) | (15, 115-130, 110) | (15, 0-15, 115) |
| (15, 55-70, 115) | (15, 110-130, 115) | (15, 175-175, 115) | (15, 0-10, 120) | (15, 60-130, 120) |
| (15, 170-175, 120) | (15, 0-5, 125) | (15, 65-135, 125) | (15, 155-175, 125) | (15, 65-175, 130) |
| (15, 70-175, 135) | (15, 70-175, 140) | (15, 0-5, 145) | (15, 70-175, 145) | (15, 0-35, 150) |
| (15, 50-175, 150) | (15, 0-175, 155) | (15, 0-175, 160) | (15, 0-165, 165) | (15, 0-170, 170) |
| (15, 0-175, 175) | | | | |

TABLE 6
(ϕ[°], θ[°], ψ[°])

| | | | | |
|---|---|---|---|---|
| (20, 0-175, 0) | (20, 95-175, 5) | (20, 115-175, 10) | (20, 120-175, 15) | (20, 0-10, 20) |
| (20, 120-175, 20) | (20, 0-20, 25) | (20, 125-175, 25) | (20, 0-25, 30) | (20, 125-175, 30) |
| (20, 0-30, 35) | (20, 125-175, 35) | (20, 0-35, 40) | (20, 115-175, 40) | (20, 0-35, 45) |
| (20, 95-175, 45) | (20, 0-40, 50) | (20, 65-170, 50) | (20, 0-175, 55) | (20, 0-175, 60) |
| (20, 5-70, 65) | (20, 110-175, 65) | (20, 5-65, 70) | (20, 115-175, 70) | (20, 5-60, 75) |
| (20, 120-175, 75) | (20, 0-60, 80) | (20, 120-175, 80) | (20, 0-60, 85) | (20, 120-140, 85) |
| (20, 160-175, 85) | (20, 0-60, 90) | (20, 120-135, 90) | (20, 165-175, 90) | (20, 0-60, 95) |
| (20, 120-130, 95) | (20, 170-175, 95) | (20, 0-25, 100) | (20, 40-60, 100) | (20, 120-130, 100) |
| (20, 0-20, 105) | (20, 45-60, 105) | (20, 120-130, 105) | (20, 0-15, 110) | (20, 50-65, 110) |
| (20, 115-130, 110) | (20, 0-10, 115) | (20, 55-70, 115) | (20, 110-125, 115) | (20, 0-5, 120) |
| (20, 60-130, 120) | (20, 175-175, 120) | (20, 60-130, 125) | (20, 170-175, 125) | (20, 65-130, 130) |
| (20, 155-175, 130) | (20, 65-175, 135) | (20, 0-5, 140) | (20, 65-175, 140) | (20, 0-25, 145) |
| (20, 60-175, 145) | (20, 0-175, 150) | (20, 0-175, 155) | (20, 0-175, 160) | (20, 0-175, 165) |
| (20, 0-155, 170) | (20, 0-165, 175) | | | |

TABLE 7
(ϕ[°], θ[°], ψ[°])

| | | | | |
|---|---|---|---|---|
| (25, 140-175, 5) | (25, 135-175, 10) | (25, 0-15, 15) | (25, 135-175, 15) | (25, 0-25, 20) |
| (25, 135-175, 20) | (25, 0-30, 25) | (25, 130-175, 25) | (25, 0-35, 30) | (25, 130-175, 30) |
| (25, 0-35, 35) | (25, 130-175, 35) | (25, 0-40, 40) | (25, 125-175, 40) | (25, 0-45, 45) |
| (25, 105-175, 45) | (25, 0-175, 50) | (25, 0-175, 55) | (25, 5-175, 60) | (25, 5-70, 65) |
| (25, 110-175, 65) | (25, 5-65, 70) | (25, 115-175, 70) | (25, 0-60, 75) | (25, 120-175, 75) |
| (25, 0-60, 80) | (25, 120-175, 80) | (25, 0-60, 85) | (25, 120-175, 85) | (25, 0-60, 90) |
| (25, 120-140, 90) | (25, 160-175, 90) | (25, 0-25, 95) | (25, 40-60, 95) | (25, 120-135, 95) |
| (25, 165-175, 95) | (25, 0-20, 100) | (25, 45-60, 100) | (25, 120-130, 100) | (25, 170-175, 100) |
| (25, 0-15, 105) | (25, 50-60, 105) | (25, 120-130, 105) | (25, 0-10, 110) | (25, 55-65, 110) |
| (25, 115-125, 110) | (25, 0-5, 115) | (25, 55-70, 115) | (25, 110-125, 115) | (25, 60-125, 120) |
| (25, 60-125, 125) | (25, 175-175, 125) | (25, 60-125, 130) | (25, 165-175, 130) | (25, 0-5, 135) |
| (25, 60-130, 135) | (25, 145-175, 135) | (25, 60-175, 140) | (25, 0-20, 140) | (25, 0-175, 145) |
| (25, 0-175, 150) | (25, 0-175, 155) | (25, 0-175, 160) | (25, 0-175, 165) | (25, 0-170, 170) |
| (25, 0-130, 175) | | | | |

TABLE 8
(ϕ[°], θ[°], ψ[°])

| | | | | |
|---|---|---|---|---|
| (30, 0-20, 10) | (30, 160-175, 10) | (30, 0-30, 15) | (30, 150-175, 15) | (30, 0-35, 20) |
| (30, 145-175, 20) | (30, 0-40, 25) | (30, 140-175, 25) | (30, 0-40, 30) | (30, 140-175, 30) |
| (30, 0-45, 35) | (30, 135-175, 35) | (30, 0-45, 40) | (30, 135-175, 40) | (30, 0-55, 45) |
| (30, 125-175, 45) | (30, 0-175, 50) | (30, 5-175, 55) | (30, 5-175, 60) | (30, 5-70, 65) |
| (30, 110-175, 65) | (30, 0-65, 70) | (30, 115-175, 70) | (30, 0-60, 75) | (30, 120-175, 75) |
| (30, 0-60, 80) | (30, 120-175, 80) | (30, 0-60, 85) | (30, 120-175, 85) | (30, 0-60, 90) |
| (30, 120-175, 90) | (30, 0-20, 95) | (30, 45-60, 95) | (30, 120-135, 95) | (30, 160-175, 95) |
| (30, 0-15, 100) | (30, 45-60, 100) | (30, 120-135, 100) | (30, 165-175, 100) | (30, 0-10, 105) |
| (30, 50-60, 105) | (30, 120-130, 105) | (30, 170-175, 105) | (30, 0-0, 110) | (30, 55-65, 110) |
| (30, 115-125, 110) | (30, 55-70, 115) | (30, 110-125, 115) | (30, 55-125, 120) | (30, 55-125, 125) |
| (30, 0-5, 130) | (30, 60-120, 130) | (30, 175-175, 130) | (30, 0-15, 135) | (30, 1 55-125, 135) |
| (30, 165-175, 135) | (30, 0-175, 140) | (30, 0-175, 145) | (30, 0-175, 150) | (30, 0-175, 155) |
| (30, 0-175, 160) | (30, 0-175, 165) | (30, 0-175, 170) | (30, 15-165, 175) | |

TABLE 9
(ϕ[°], θ[°], ψ[°])

| | | | | |
|---|---|---|---|---|
| (35, 0-40, 5) | (35, 0-45, 10) | (35, 0-45, 15) | (35, 165-175, 15) | (35, 0-45, 20) |
| (35, 155-175, 20) | (35, 0-50, 25) | (35, 150-175, 25) | (35, 0-50, 30) | (35, 145-175, 30) |
| (35, 0-50, 35) | (35, 145-175, 35) | (35, 0-55, 40) | (35, 140-175, 40) | (35, 0-75, 45) |
| (35, 135-175, 45) | (35, 5-175, 50) | (35, 5-175, 55) | (35, 5-175, 60) | (35, 0-70, 65) |
| (35, 110-175, 65) | (35, 0-65, 70) | (35, 115-175, 70) | (35, 0-60, 75) | (35, 120-175, 75) |
| (35, 0-60, 80) | (35, 120-175, 80) | (35, 0-60, 85) | (35, 120-175, 85) | (35, 0-20, 90) |
| (35, 40-60, 90) | (35, 120-175, 90) | (35, 0-15, 95) | (35, 45-60, 95) | (35, 120-140, 95) |
| (35, 155-175, 95) | (35, 0-10, 100) | (35, 50-60, 100) | (35, 120-135, 100) | (35, 160-175, 100) |
| (35, 0-0, 105) | (35, 50-60, 105) | (35, 120-130, 105) | (35, 165-175, 105) | (35, 55-65, 110) |
| (35, 115-125, 110) | (35, 170-175, 110) | (35, 55-70, 115) | (35, 110-125, 115) | (35, 175-175, 115) |
| (35, 55-120, 120) | (35, 0-5, 125) | (35, 55-120, 125) | (35, 0-15, 130) | (35, 55-120, 130) |
| (35, 0-35, 135) | (35, 50-120, 135) | (35, 175-175, 135) | (35, 0-120, 140) | (35, 160-175, 140) |
| (35, 0-175, 145) | (35, 0-175, 150) | (35, 0-175, 155) | (35, 0-175, 160) | (35, 0-175, 165) |
| (35, 10-175, 170) | (35, 50-175, 175) | | | |

TABLE 10
(ϕ[°], θ[°], ψ[°])

| | | | | |
|---|---|---|---|---|
| (40, 0-175, 0) | (40, 0-85, 5) | (40, 0-65, 10) | (40, 0-60, 15) | (40, 0-60, 20) |
| (40, 170-175, 20) | (40, 0-55, 25) | (40, 160-175, 25) | (40, 0-55, 30) | (40, 155-175, 30) |
| (40, 0-55, 35) | (40, 150-175, 35) | (40, 0-65, 40) | (40, 145-175, 40) | (40, 5-85, 45) |
| (40, 145-175, 45) | (40, 10-115, 50) | (40, 140-175, 50) | (40, 5-175, 55) | (40, 0-175, 60) |
| (40, 0-70, 65) | (40, 110-175, 65) | (40, 0-65, 70) | (40, 115-175, 70) | (40, 0-60, 75) |
| (40, 120-175, 75) | (40, 0-60, 80) | (40, 120-175, 80) | (40, 0-20, 85) | (40, 40-60, 85) |
| (40, 120-175, 85) | (40, 0-15, 90) | (40, 45-60, 90) | (40, 120-175, 90) | (40, 0-10, 95) |
| (40, 50-60, 95) | (40, 120-175, 95) | (40, 0-0, 100) | (40, 50-60, 100) | (40, 120-140, 100) |
| (40, 155-175, 100) | (40, 50-60, 105) | (40, 120-135, 105) | (40, 160-175, 105) | (40, 50-65, 110) |
| (40, 115-130, 110) | (40, 165-175, 110) | (40, 55-70, 115) | (40, 110-125, 115) | (40, 170-175, 115) |
| (40, 0-5, 120) | (40, 50-120, 120) | (40, 175-175, 120) | (40, 0-10, 125) | (40, 50-120, 125) |
| (40, 0-25, 130) | (40, 50-115, 130) | (40, 0-115, 135) | (40, 0-115, 140) | (40, 175-175, 140) |
| (40, 0-120, 145) | (40, 155-175, 145) | (40, 0-175, 150) | (40, 0-175, 155) | (40, 0-175, 160) |
| (40, 5-175, 165) | (40, 25-175, 170) | (40, 15-175, 175) | | |

TABLE 11
(ϕ[°], θ[°], ψ[°])

| | | | | |
|---|---|---|---|---|
| (45, 0-175, 0) | (45, 0-175, 5) | (45, 0-90, 10) | (45, 0-75, 15) | (45, 0-70, 20) |
| (45, 0-65, 25) | (45, 170-175, 25) | (45, 0-65, 30) | (45, 165-175, 30) | (45, 0-65, 35) |
| (45, 155-175, 35) | (45, 5-75, 40) | (45, 155-175, 40) | (45, 10-90, 45) | (45, 150-175, 45) |
| (45, 5-105, 50) | (45, 145-175, 50) | (45, 0-175, 55) | (45, 0-175, 60) | (45, 0-70, 65) |
| (45, 110-175, 65) | (45, 0-65, 70) | (45, 115-175, 70) | (45, 0-60, 75) | (45, 120-175, 75) |
| (45, 0-20, 80) | (45, 40-60, 80) | (45, 120-175, 80) | (45, 0-15, 85) | (45, 45-60, 85) |
| (45, 120-175, 85) | (45, 0-10, 90) | (45, 45-60, 90) | (45, 120-175, 90) | (45, 0-0, 95) |
| (45, 50-60, 95) | (45, 120-175, 95) | (45, 50-60, 100) | (45, 120-175, 100) | (45, 50-60, 105) |
| (45, 120-135, 105) | (45, 155-175, 105) | (45, 50-65, 110) | (45, 115-130, 110) | (45, 160-175, 110) |
| (45, 0-5, 115) | (45, 50-70, 115) | (45, 110-125, 115) | (45, 165-175, 115) | (45, 0-10, 120) |
| (45, 50-120, 120) | (45, 170-175, 120) | (45, 0-25, 125) | (45, 45-115, 125) | (45, 175-175, 125) |
| (45, 0-115, 130) | (45, 0-110, 135) | (45, 0-110, 140) | (45, 0-110, 145) | (45, 175-175, 145) |
| (45, 0-130, 150) | (45, 145-175, 150) | (45, 0-175, 155) | (45, 5-175, 160) | (45, 15-175, 165) |
| (45, 10-175, 170) | (45, 0-175, 175) | | | |

TABLE 12
(ϕ[°], θ[°], ψ[°])

| | | | | |
|---|---|---|---|---|
| (50, 0-175, 0) | (50, 0-175, 5) | (50, 0-175, 10) | (50, 0-95, 15) | (50, 0-80, 20) |
| (50, 0-75, 25) | (50, 0-70, 30) | (50, 175-175, 30) | (50, 5-70, 35) | (50, 165-175, 35) |
| (50, 10-80, 40) | (50, 160-175, 40) | (50, 5-95, 45) | (50, 155-175, 45) | (50, 0-105, 50) |
| (50, 150-175, 50) | (50, 0-120, 55) | (50, 145-175, 55) | (50, 0-175, 60) | (50, 0-70, 65) |
| (50, 110-175, 65) | (50, 0-65, 70) | (50, 115-175, 70) | (50, 0-25, 75) | (50, 40-60, 75) |
| (50, 120-175, 75) | (50, 0-15, 80) | (50, 45-60, 80) | (50, 120-175, 80) | (50, 0-10, 85) |
| (50, 45-60, 85) | (50, 120-175, 85) | (50, 0-0, 90) | (50, 50-60, 90) | (50, 120-175, 90) |
| (50, 50-60, 95) | (50, 120-175, 95) | (50, 50-60, 100) | (50, 120-175, 100) | (50, 50-60, 105) |
| (50, 120-175, 105) | (50, 0-5, 110) | (50, 50-65, 110) | (50, 115-135, 110) | (50, 155-175, 110) |
| (50, 0-10, 115) | (50, 50-70, 115) | (50, 110-125, 115) | (50, 160-175, 115) | (50, 0-20, 120) |
| (50, 45-120, 120) | (50, 165-175, 120) | (50, 0-115, 125) | (50, 170-175, 125) | (50, 0-110, 130) |
| (50, 175-175, 130) | (50, 0-105, 135) | (50, 0-105, 140) | (50, 0-100, 145) | (50, 0-110, 150) |
| (50, 170-175, 150) | (50, 5-175, 155) | (50, 15-175, 160) | (50, 5-175, 165) | (50, 0-175, 170) |
| (50, 0-175, 175) | | | | |

TABLE 13
(ϕ[°], θ[°], ψ[°])

| | | | | |
|---|---|---|---|---|
| (55, 0-175, 0) | (55, 0-175, 5) | (55, 0-175, 10) | (55, 0-125, 15) | (55, 155-175, 15) |
| (55, 0-95, 20) | (55, 0-85, 25) | (55, 5-80, 30) | (55, 10-80, 35) | (55, 175-175, 35) |
| (55, 5-90, 40) | (55, 165-175, 40) | (55, 0-95, 45) | (55, 160-175, 45) | (55, 0-105, 50) |
| (55, 155-175, 50) | (55, 0-115, 55) | (55, 150-175, 55) | (55, 0-130, 60) | (55, 145-175, 60) |
| (55, 0-70, 65) | (55, 110-175, 65) | (55, 0-25, 70) | (55, 40-65, 70) | (55, 115-175, 70) |
| (55, 0-15, 75) | (55, 45-60, 75) | (55, 120-175, 75) | (55, 0-10, 80) | (55, 45-60, 80) |
| (55, 120-175, 80) | (55, 0-0, 85) | (55, 50-60, 85) | (55, 120-175, 85) | (55, 50-60, 90) |
| (55, 120-175, 90) | (55, 50-60, 95) | (55, 120-175, 95) | (55, 50-60, 100) | (55, 120-175, 100) |
| (55, 0-0, 105) | (55, 50-60, 105) | (55, 120-175, 105) | (55, 0-10, 110) | (55, 45-65, 110) |
| (55, 115-175, 110) | (55, 0-20, 115) | (55, 45-70, 115) | (55, 110-130, 115) | (55, 155-175, 115) |
| (55, 0-120, 120) | (55, 160-175, 120) | (55, 0-115, 125) | (55, 165-175, 125) | (55, 0-110, 130) |
| (55, 170-175, 130) | (55, 0-105, 135) | (55, 175-175, 135) | (55, 0-100, 140) | (55, 0-95, 145) |
| (55, 5-95, 150) | (55, 10-110, 155) | (55, 170-175, 155) | (55, 5-175, 160) | (55, 0-175, 165) |
| (55, 0-175, 170) | (55, 0-175, 175) | | | |

TABLE 14
(ϕ[°], θ[°], ψ[°])

| | | | | |
|---|---|---|---|---|
| (60, 0-175, 0) | (60, 0-175, 5) | (60, 0-175, 10) | (60, 0-175, 15) | (60, 0-115, 20) |
| (60, 165-175, 20) | (60, 5-95, 25) | (60, 10-90, 30) | (60, 5-90, 35) | (60, 0-95, 40) |
| (60, 175-175, 40) | (60, 0-100, 45) | (60, 170-175, 45) | (60, 0-105, 50) | (60, 165-175, 50) |
| (60, 0-115, 55) | (60, 160-175, 55) | (60, 0-125, 60) | (60, 155-175, 60) | (60, 0-30, 65) |
| (60, 40-70, 65) | (60, 110-135, 65) | (60, 145-175, 65) | (60, 0-15, 70) | (60, 45-65, 70) |
| (60, 115-175, 70) | (60, 0-10, 75) | (60, 45-60, 75) | (60, 120-175, 75) | (60, 0-0, 80) |
| (60, 50-60, 80) | (60, 120-175, 80) | (60, 50-60, 85) | (60, 120-175, 85) | (60, 50-60, 90) |
| (60, 120-175, 90) | (60, 50-60, 95) | (60, 120-175, 95) | (60, 0-0, 100) | (60, 50-60, 100) |
| (60, 120-175, 100) | (60, 0-10, 105) | (60, 45-60, 105) | (60, 120-175, 105) | (60, 0-15, 110) |
| (60, 45-65, 110) | (60, 115-175, 110) | (60, 0-30, 115) | (60, 40-70, 115) | (60, 110-135, 115) |
| (60, 145-175, 115) | (60, 0-125, 120) | (60, 155-175, 120) | (60, 0-115, 125) | (60, 160-175, 125) |
| (60, 0-105, 130) | (60, 165-175, 130) | (60, 0-100, 135) | (60, 170-175, 135) | (60, 0-95, 140) |
| (60, 175-175, 140) | (60, 5-90, 145) | (60, 10-90, 150) | (60, 5-95, 155) | (60, 0-115, 160) |
| (60, 165-175, 160) | (60, 0-175, 165) | (60, 0-175, 170) | (60, 0-175, 175) | |

Despite when the Euler angles of the crystal substrate 3 are within the range of the Euler angles equivalent to the range of (φ, θ, ψ) in Table 2 to Table 14, a bulk wave that propagates through the crystal substrate 3 has a lower velocity than an acoustic wave that propagates through the lithium tantalate layer 6. The symmetry of quartz crystal is D₃⁶ or D₃⁴ in Schoenflies notation, or a point group of 32 in international notation. Document 1 (Hiroshi KAMEYAMA, Symmetry of Elastic Vibration in Quartz Crystal, Japanese Journal of Applied Physics, Volume 23, Number S1) describes that crystal has high symmetry with respect to the polar coordinates (θ, φ). The following description expresses that various features f (θ, φ) relating to the acoustic vibrations such as velocity, an elastic constant, displacement, or a frequency constant are unchangeable by the symmetry operation.

FIG. 8 is a stereographic projection showing symmetry of acoustic vibrations in a quartz crystal. In FIG. 8, an inversion operation I is added to the symmetry operation on the crystal point group D₃-32, and the stereographic projection is thus the same or substantially the same as the stereographic projection of the crystal point group D_{3d}-3m (with a bar above 3). In FIG. 8, black circular plots indicate equivalent points of the upper hemisphere, white circular plots indicate equivalent points of the lower hemisphere, elliptical plots indicate two-rotation axes, and a triangular plot indicates a three-rotation axis.

The three-rotation axis in FIG. 8 corresponds to the Z axis in notation of the Euler angles. In FIG. 8, multiple axes such as about 0° or about 60° (2π/6) extend perpendicularly or substantially perpendicularly to the Z axis. As illustrated in FIG. 8, quartz crystal exhibits the same behavior of the acoustic vibrations every time when rotating about the Z axis in a direction of φ by about 120° (4π/6). Thus, the velocity at about 0° to about 60° and the velocity at about 60° to about 120° form symmetry with respect to the axis of about 60°. Thus, as illustrated in Table 2 to Table 14, showing the orientations of the Euler angles when φ is about 0° to about 60° can express the characteristics of all the orientations (all the Euler angles) of crystal while other orientations are regarded as being equivalent to the above orientations. The equivalent orientations include the following angles in 1) and 2). 1) Euler angles when rotated by about 0°, about 120°, or about 240° in the direction of φ about the Z axis. 2) Euler angles when rotated by about 60°, about 180°, or about 300° in the direction of φ about the Z axis and then subjected to the inversion operation (reverse relationship of the crystal substrate).

Hereafter, advantageous effects of effectively reducing or preventing a higher order mode in a wide band with a bulk wave that propagates through the crystal substrate 3 having a lower velocity than an acoustic wave that propagates through the lithium tantalate layer 6 is described in detail.

With reference to FIG. 1, a second preferred embodiment and a third preferred embodiment of the present invention are described. The second preferred embodiment differs from the first preferred embodiment in that a bulk wave that propagates through the crystal substrate 3 has a higher velocity than an acoustic wave that propagates through the lithium tantalate layer 6. More specifically, the second preferred embodiment differs from the first preferred embodiment in the Euler angles (φ, θ, ψ) of the crystal substrate 3. The acoustic wave device according to the third preferred embodiment differs from an acoustic wave device in which the Euler angles (φ, θ, ψ) of the crystal substrate 3 have the phase characteristics illustrated in FIG. 4. The acoustic wave device according to the third preferred embodiment substantially has the same or substantially the same structure as the acoustic wave device according to the first preferred embodiment.

The acoustic wave device according to the second preferred embodiment and the acoustic wave device according to the third preferred embodiment are compared in terms of the phase characteristics. The design parameters of the acoustic wave devices are as follows.
aluminum oxide layer 4: a thickness of about 1.6 μm
low velocity film 5: a material of SiO₂ and a thickness of about 300 nm
lithium tantalate layer 6: a material of LiTaO₃ and a thickness of about 400 nm
IDT electrode 7: a layer structure including a Ti layer, an AlCu layer, and a Ti layer sequentially laminated on the lithium tantalate layer 6, thicknesses of about 12 nm, about 100 nm, and about 4 nm from the side closer to the lithium tantalate layer 6, a wavelength λ of about 2 μm, and a duty of about 0.5

In the second preferred embodiment, the Euler angles (φ, θ, ψ) of the crystal substrate 3 are set as (about 0°, about 180°, about 90°). In this case, a slow transversal wave that propagates through the crystal substrate 3 has a velocity of about 3915.4 m/s. A surface acoustic wave that propagates through the lithium tantalate layer 6 has a velocity of about 3900 m/s. Thus, the slow transversal wave that propagates through the crystal substrate 3 has a higher velocity than the surface acoustic wave that propagates through the lithium tantalate layer 6.

In the third preferred embodiment, the Euler angles (φ, θ, ψ) of the crystal substrate 3 are set as (about 0°, about 200°, about 60°). In this case, a slow transversal wave that propagates through the crystal substrate 3 has a velocity of about 3538.2 m/s. A surface acoustic wave that propagates through the lithium tantalate layer 6 has a velocity of about 3900 m/s. Thus, the slow transversal wave that propagates through the crystal substrate 3 has a lower velocity than the surface acoustic wave that propagates through the lithium tantalate layer 6.

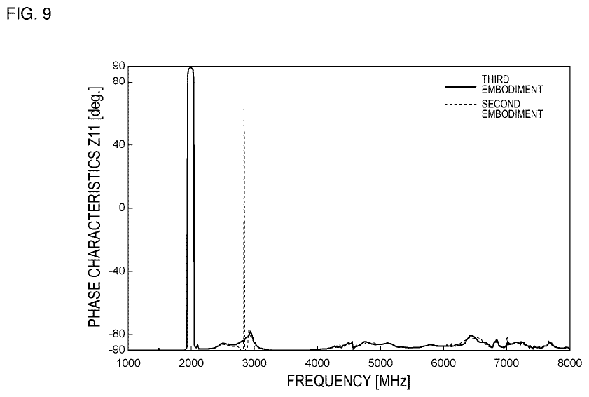

FIG. 9 is a diagram showing the phase characteristics of the acoustic wave devices according to the second preferred embodiment and the third preferred embodiment.

As illustrated in FIG. 9, in the second preferred embodiment, the higher order mode can be reduced or prevented in a wide band of frequencies higher than or equal to about 1.5 times of the resonance frequency. In the second preferred embodiment, the higher order mode occurs in a band of frequencies lower than or equal to about 1.5 times of the resonance frequency. In the third preferred embodiment, on the other hand, the higher order mode can be reduced or prevented in a wide band including a band of frequencies lower than or equal to about 1.5 times of the resonance frequency. Thus, in the second and third preferred embodiments, the crystal substrate 3 can leak a higher order mode, and can thus further efficiently reduce or prevent the higher order mode in a wide band.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a crystal substrate;
an aluminum oxide layer on the crystal substrate;
a piezoelectric layer on the aluminum oxide layer; and
an interdigital transducer (IDT) electrode on the piezoelectric layer and including a plurality of electrode fingers.

2. The acoustic wave device according to claim 1, wherein the piezoelectric layer is a lithium tantalate layer or a lithium niobate layer.

3. The acoustic wave device according to claim 2, wherein the piezoelectric layer has a cut-angle of about 20°-rotated Y-cut X-propagation to about 60°-rotated Y-cut X-propagation.

4. The acoustic wave device according to claim 1, further comprising:
a low velocity film between the aluminum oxide layer and the piezoelectric layer; wherein
a bulk wave that propagates through the low velocity film has a lower velocity than a bulk wave that propagates through the piezoelectric layer.

5. The acoustic wave device according to claim 4, wherein the low velocity film is a silicon oxide film.

6. The acoustic wave device according to claim 1, wherein a bulk wave that propagates through the crystal substrate has a lower velocity than an acoustic wave that propagates through the piezoelectric layer.

7. The acoustic wave device according to claim 6, wherein the crystal substrate has Euler angles (φ, θ, ψ) of (about 0°±about 2.5°, θ, about 90°±about 2.5°), and θ in the Euler angles of the crystal substrate satisfies about 185°≤θ≤about 240°.

8. The acoustic wave device according to claim 7, wherein, when a wavelength defined by an electrode finger pitch of the plurality of electrode fingers of the IDT electrode is denoted with λ and a thickness of the aluminum oxide layer is denoted with t, a relationship between θ in the Euler angles of the crystal substrate and the thickness t is any of combinations in Table 1:
TABLE 1

| θ [°] of crystal substrate | thickness t [λ] of aluminum oxide layer |
|---|---|
| 185 ≤ θ < 190 | 0.8 ≤ t ≤ 1.15 |
| 190 ≤ θ < 195 | 0.8 ≤ t ≤ 1 |
| 195 ≤ θ < 200 | 0.8 ≤ t ≤ 1 |
| 200 ≤ θ < 205 | 0.8 ≤ t ≤ 1.05 |
| 205 ≤ θ < 210 | 0.8 ≤ t ≤ 1.1 |
| 210 ≤ 0 ≤ 215 | 0.8 ≤ t ≤ 1.05 |
| 215 ≤ θ < 220 | 0.8 ≤ t ≤ 1.05 |
| 220 ≤ θ < 225 | 0.8 ≤ t ≤ 1.05 |
| 225 ≤ θ < 230 | 0.8 ≤ t ≤ 1 |
| 230 ≤ θ < 235 | 0.8 ≤ t ≤ 0.95 |
| 235 ≤ 0 ≤ 240 | 0.8 ≤ t ≤ 0.9. |

9. The acoustic wave device according to claim 4, wherein the low velocity film includes glass, a silicon oxynitride, a lithium oxide, a tantalum pentoxide, or a compound obtained by adding fluorine, carbon, or boron to a silicon oxide as a main component.

10. The acoustic wave device according to claim 1, further comprising a pair of reflectors on both sides of the IDT electrode in a propagation direction.
